(19) United States
(12) Patent Application Publication
(10) Pub. No.: US 2004/0046224 A1
(43) Pub. Date: Mar. 11, 2004

(54) Schottky-diode semiconductor device

(76) Inventors: Pierre Rossel, Rossel-Executrix of the Estate of Pierre (FR); Frederic Morancho, Lauragais (FR); Nathalie Cezac, Providence (FR); Henri Tranduc, clos du Pin (FR)

Correspondence Address: CONLEY ROSE, P.C., P. O. BOX 3267, HOUSTON, TX, 77253-3267, US

(21) Appl. No.: 10/239,629

(22) PCT Filed: Apr. 10, 2001
(86) PCT No.: PCT/FR01/01101

(30) Foreign Application Priority Data
Apr. 10, 2000 (FR) 00-04583

(51) Int. Cl. H01L 27/095

(52) U.S. Cl. 257/471

(57) ABSTRACT

The invention concerns a Schottky-diode semiconductor device, comprising a substrate consisting of first (2) and second (3) semiconductor layers having the same type of conduction tiered up in said substrate, the second layer (3) being more highly doped than the first (2), said substrate having first (4) and second (5) main surfaces in contact with first (8) and second (6) electrodes, a Schottky barrier being formed between the first electrode (8) and said first layer. The invention is characterised in that the plurality of islands (9) having a type of conduction opposite to that of the first layer (2) are arranged in beds spaced apart in the thickness of said layer (2).

The present invention relates to a semiconductor device and it more particularly concerns improvements made to Schottky or “JBS rectifier” (Junction Barrier Schottky rectifier) type diodes.

Schottky diodes basically comprise a metal or a metal alloy placed onto a semiconductor. The diode is usually constituted by an N- or P-type active region, placed onto a region of the same type, i.e. N or P, but much more heavily doped. The metal from which the Schottky contact is made constitutes the anode, while the other face of the substrate which is metallized and which constitutes an ohmic contact, is called the cathode.

Two types of operation, one of off-state and one of on-state, are normally defined for diodes and in particular for Schottky diodes. Each of these states is further defined by an operating characteristic: voltage stability for the off-state and voltage drop for the on-state.

Thus, sustained reverse voltage stability (off-state) depends on the doping of the N- or P-type zone, and the lower this is, the greater the voltage stability. For Schottky diodes known from the prior art, functioning in off-state, the limit of voltage stability is usually around 100 volts.

Voltage drop in the on-state is the sum of the voltage drop in the semiconductor layer charge associated with the Schottky barrier, and the drop in ohmic voltage in the bulk semiconductor.

Voltage-drop values commonly encountered for Schottky diodes functioning in on-state are of the order of 0.5 volts.

In order to improve the operating characteristics in the off-state as well as the on-state of Schottky diodes, JBS rectifier Schottky diodes were devised. These second-generation diodes are structurally identical overall to the previous Schottky diodes, but can nevertheless be distinguished from them by the fact that they include semiconductor inserts of the opposite type to the semiconductor layer associated with the Schottky barrier. This arrangement makes it possible to limit the reduction mechanism of the Schottky barrier under applied high voltage and to limit the reverse current of the diode.

The voltage stability capacity in these devices can usually reach approximately 200 volts and the voltage drop, in on-state, is of the order of 0.25 volts.

The present invention therefore aims to overcome the drawbacks of the devices known from the prior art, by proposing improvements made to these devices, which make it possible to obtain improved operating characteristics, in off-state as well as in on-state.

This aim of the invention is achieved with a Schottky-diode type semiconductor device, comprising a substrate constituted by first and second semiconductive layers of the same conduction type superimposed in said substrate, the second layer being more heavily doped than the first, said substrate presenting first and second main surfaces in contact with first and second electrodes, a Schottky barrier being formed between said first electrode and said first layer, a plurality of islands of a conduction type opposite to that of said first layer being arranged in beds spaced apart in the thickness of said layer.

Other characteristics and advantages of the present invention will emerge from the description given below, with reference to the attached drawings which illustrate an embodiment thereof which is not in any way limiting.

In the Figures:

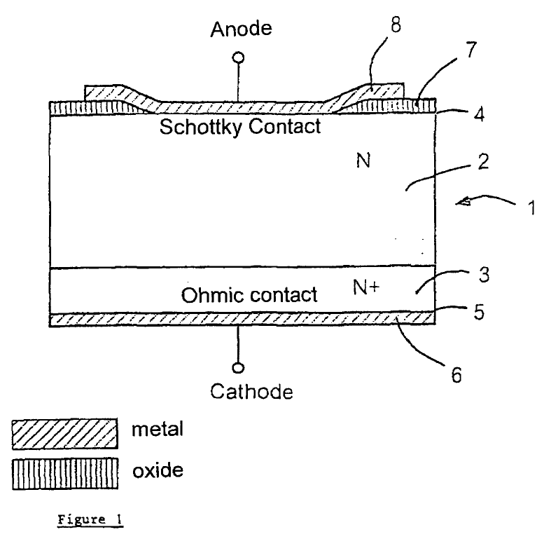

FIG. 1 illustrates the structure of a Schottky diode;

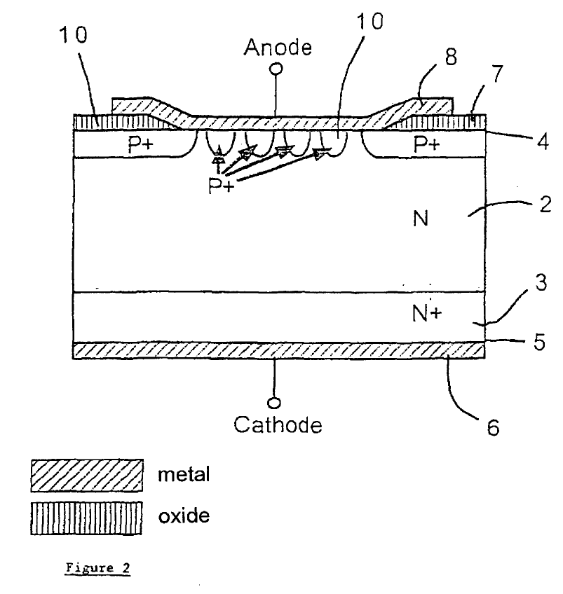

FIG. 2 illustrates the structure of a JBS rectifier type diode;

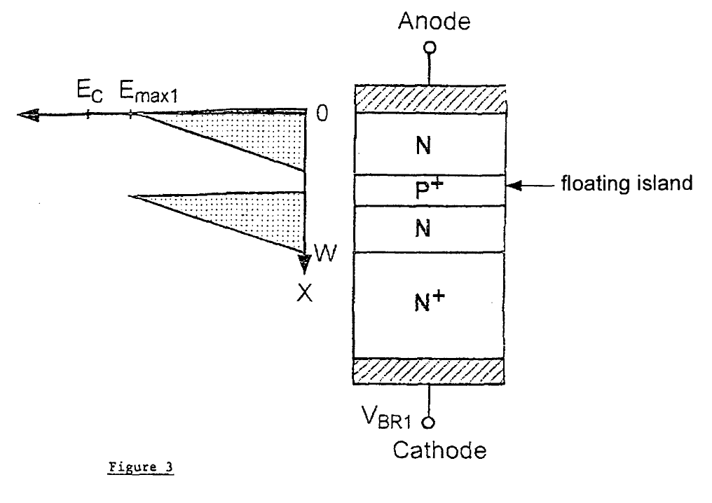

FIG. 3 illustrates the distribution of the electric field in an example of a structure containing a bulk floating island;

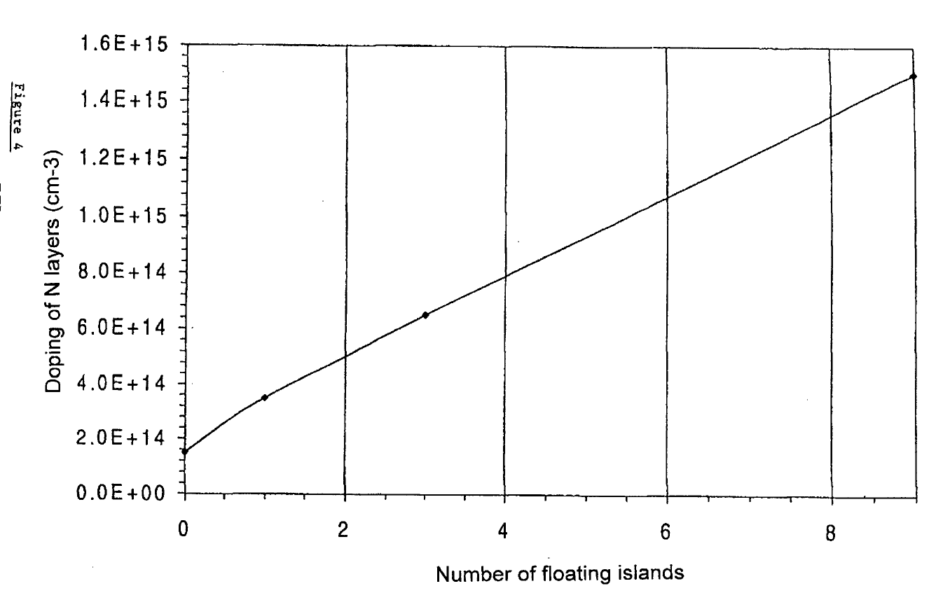

FIG. 4 shows the evolution of the order of magnitude of doping in relation to the number of islands contained in a semiconductor device which is a subject of the invention;

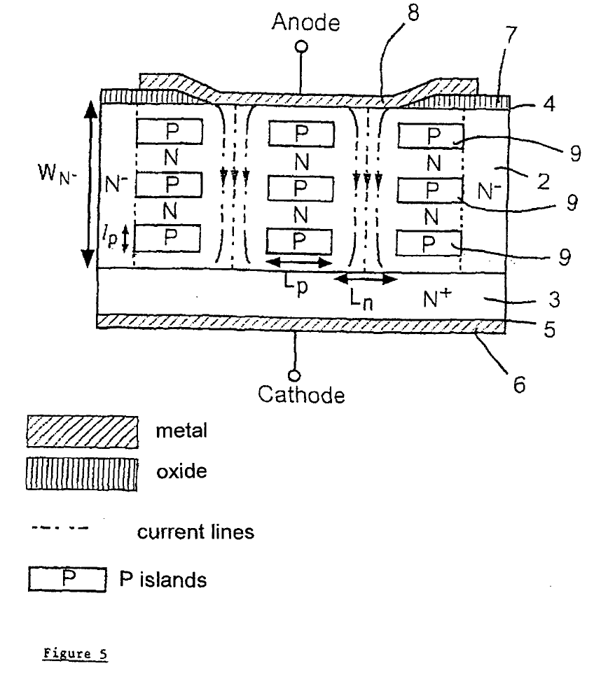

FIG. 5 is a sectional view illustrating a semiconductor device of Schottky diode type according to the invention;

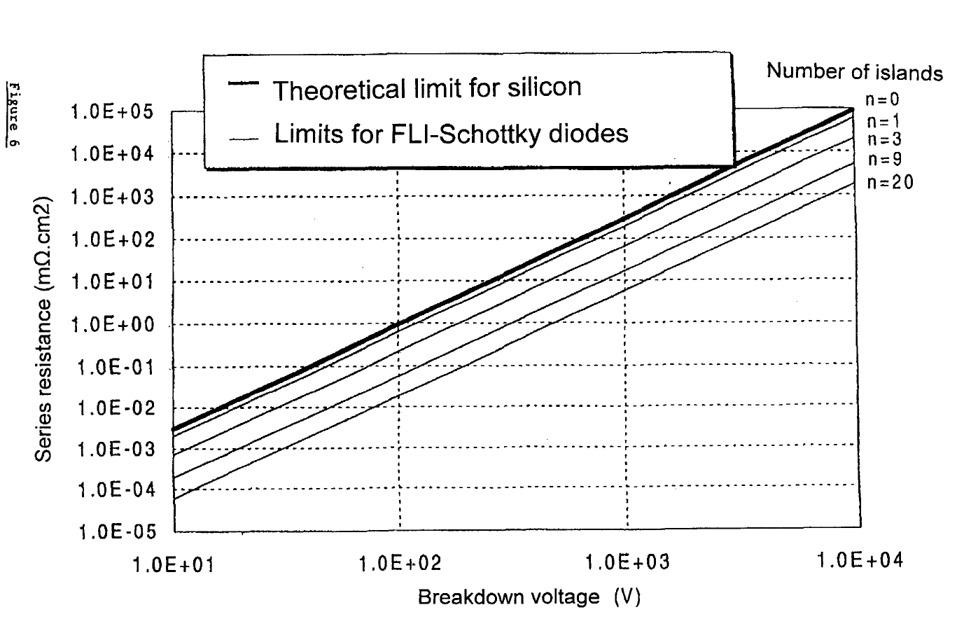

FIG. 6 illustrates the evolution of the order of magnitude of the series resistance in relation to the reverse voltage stability for different numbers of beds of floating islands;

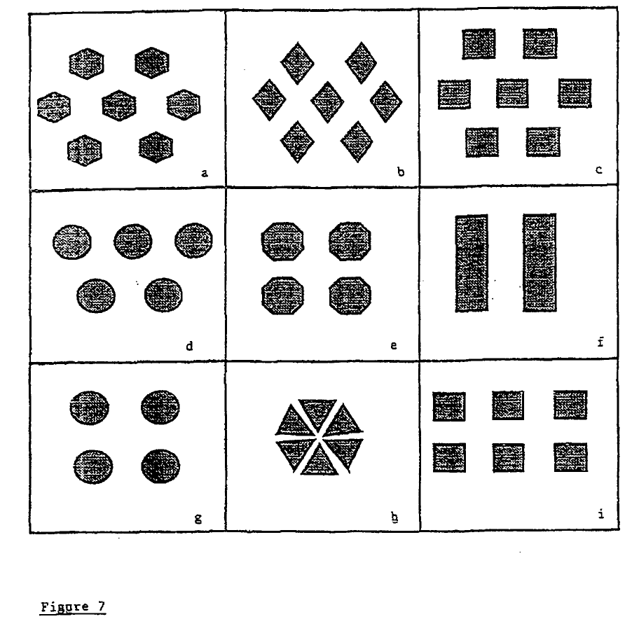

FIG. 7 illustrates several geometric shapes of floating islands;

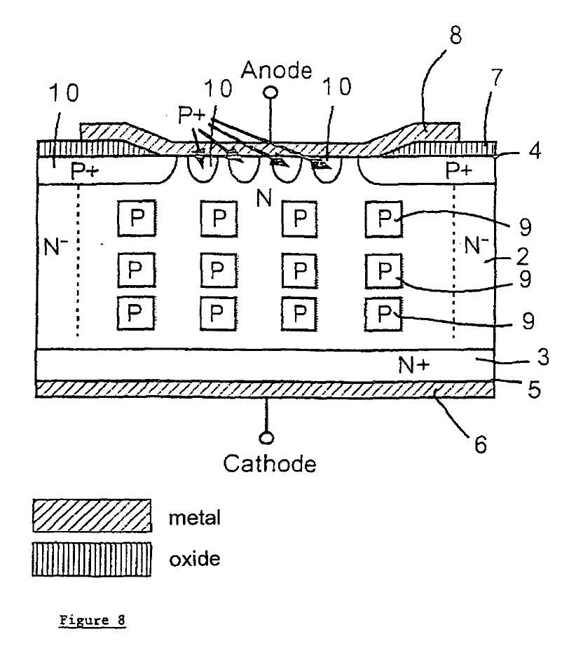

FIG. 8 is a sectional view illustrating a JBS diode type semiconductor device.

According to a first preferred embodiment of the semiconductor device which is a subject of the invention (refer to FIGS. 1 and 5), this comprises a semiconducting substrate 1 with two main surfaces 4, 5 arranged in opposition relative to each other. The semiconducting substrate 1 is composed of a first semiconducting region 2, 3 of a first type of conduction with an N-type doped (first type or donor) or P doped (second type or acceptor) first layer 2, and an N-type doped (first type or donor) or P-type doped (second type or acceptor) second layer 3. The first layer 2, of first or second type, is adjacent to the first main surface 4, whilst the second layer 3, of first or second type, is adjacent to the second main surface 5.

However, the semiconducting substrate comprises a first layer 2 and a second layer 3 which are of identical types, i.e. both are of first or second type.

The first main surface 4 is covered on one hand with a peripheral film 7, in particular oxide-based, and is arranged so as to be in ohmic contact with the first layer 2 at a central electrode 8.

This central electrode 8 forms the anode of the device and is made from a material forming a Schottky-type contact with the semiconductor.

This material is chosen from in particular molybdenum, tungsten, platinum, palladium or an equivalent, it can also be a metal alloy (silicide etc.).

This electrode 8 is arranged in such a way as to be adjacent with the peripheral film 7 and forms a Schottky barrier with the first layer 2, at the largely central zone of the semiconducting substrate 1.

The second main surface 5 also co-operates with a second electrode 6 which is arranged so as to be in ohmic contact with the second layer 3. This electrode 6 made from a metal constitutes the cathode of the semiconductor device which is a subject of the invention.

According to another characteristic, the second layer 3 of first or second type is more heavily doped, in terms of the quantity of impurities introduced into the layer, compared with the first layer of first or second type.

It can be noted for example that the impurities introduced into the layer of first type will in particular be arsenic and phosphorus, whilst the impurities introduced into the layer of second type will in particular be boron.

Accorcing to a second preferred embodiment of the semiconductor device which is a subject of the invention (refer to FIGS. 2 and 8), this comprises a semiconducting substrate 1 identical in its constitution to the semiconductor device 1 as described in the first preferred embodiment, and differs from it in that it contains, in the first layer 2 of first type (N) or second type (P), a plurality of semiconducting regions 10 of opposite type of conduction to those which surround it, the plurality of regions 10 extending from the first main surface 4 and from the electrode 8 to the inside of the first layer 2.

According to a third preferred embodiment of the semiconductor device which is a subject of the invention, this comprises in a much more general manner a semiconducting substrate 1 containing at least one layer 2 or 3 of first or second type of conduction in which, and according to an advantageous characteristic of the invention, there are incorporated or included in the layer 2 of the semiconducting substrate 1 of first or second type, a plurality of islands 9 of opposite type to that of the semiconductor in which they are placed. Thus, these islands 9 can be of first type (N) or second type (P). These islands 9 are arranged in beds spaced apart, in the thickness of at least the layer 2 by localised epitaxy techniques in successive layers, by high-energy ion implantation, by MBE (molecule beam epitaxy) combined with photolithography mask processes or standard processes (oxidation, thermal diffusion, low-energy ion implantation).

According to another advantageous characteristic of the invention, these islands 9 can assume various profiles (square, rectangle, triangle, circle, hexagon, octagon, or more generally polygonal etc.) or be arranged in the form of bands of homogenous or mixed patterns, optionally superimposed on each other in layers or being positioned in a random manner, and thus able, according to the shape of the patterns, to present covering zones of the thickness of the superimposed layers.

The islands 9 can be aligned or non-aligned, equidistant or non-equidistant, homogenous or non-homogenous, from the point of view of their characteristic directions (thickness, length and width).

The islands 9, of first or second type, can be uniformly or non-uniformly doped: there may thus be a doping gradient or this doping can be distributed according to a Gaussian law or another form of distribution. According to another characteristic, the islands 9 can have a geometric shape, when they have a polygonal cross section, with rounded corners.

By way of example, reference can be made to FIG. 7 which illustrates different configurations and distributions of islands 9. The islands represented are hexagonal in a, lozenges in b, squares in c and i, circular in d and g, octagonal in e and rectangular in f and triangular in h.

Moreover, an island 9 can measure for example from 2 to 100 μm in one of its characteristic directions, and for example from 2 to 10 μm in the other of its characteristic directions, i.e. in practice in a ratio of 1 to 10 between the two characteristic directions.

Furthermore, provision may be made to provide per diode, N spaced-apart beds of islands 9 in the first layer 2, each bed comprising between 1 and 500 islands 9, N varying from 1 to 50.

The inclusion of a plurality of doped islands 9 in a layer 2 of semiconducting substrate 1 of first or second type, makes it possible to create, in reverse operation (off-state), a reduction of the overall electric field by a mechanism for distributing the latter at each of the islands.

In such a structure, (cf. FIG. 3), the electric field is divided by the number of islands and the reverse voltage stability is therefore increased.

It is also shown that for a fixed voltage stability, the doping of the layer in which the islands are incorporated is an increasing function of the number of islands (cf. FIG. 4).

In operation (on-state) and in order to allow the passage of the current between the anode and the cathode, the islands 9 are in the form of spaced-apart grids (cf. FIG. 5). In this Figure, which illustrates a section of a Schottky diode according to the invention, the layer 3 of semiconductor of first or second type has been shown in ohmic contact with the cathode, the other layer 2 of semiconductor of first or second type, forming a Schottky barrier with the anode and in which the plurality of islands 9 is included.

These islands 9 are constituted in particular by semiconducting bands of first or second type; the choice of the type of islands 9 being however of an opposite type compared with the type of semiconductor layer in which they are included.

The inclusion of the islands 9 in the semiconducting substrate is therefore not continuous and therefore has inter-island spaces through which the current can circulate between the anode and the cathode.

Given that, globally, the doping of the conduction zone is higher than in a standard device, there is a reduction in resistivity and therefore resistance, which leads to a smaller drop in voltage. By way of an example, reference may be made to FIG. 6 which shows the evolution of the value of the series resistance created in the layer in which the islands are incorporated, in relation to the reverse voltage stability of the dipole; in this example, the dipole is a Schottky diode. From this FIG. 6, it can be deduced that, the greater the number of islands, the more the resistance decreases, and for example, the dipoles according to the invention (in particular the Schottky diodes), having islands 9 (N=20), with a reverse voltage stability of the order of 600 volts, present performance values for series resistance, and therefore for forward voltage drop, that are identical to the Schottky diodes of 100 volts of voltage stability according to the prior art.

As the operating mechanisms previously devised for a dipole in particular of Schottky diode type containing a plurality of floating islands, are identical when these islands are included in a dipole structure of for example JBS diode type, and the operating values, in off-state as well as on-state, for such a dipole (cf. FIG. 8), are identical to those found for equivalent devices in the prior art, but for a reverse voltage stability value which is of the order of 600 volts (about 100 to 200 volts for the devices of the prior art), and which can reach 1000 volts.

The main applications envisaged using this new structure of semiconducting component substrate are in particular in the field of current rectification (alternating/direct), or as a free-wheel diode integrally or discretely fitted with another component which acts as power breaker (coils or bridge arm, chopper, inverter control etc.).

This component can in particular be developed in the field of lighting (electronic ballast). This electronic component can also be used in control of motors, or automobile electronics (rectifier component for the alternator, or a component incorporated into integrated power circuits.

The present invention is of course not limited to the embodiments described and represented above, but it encompasses all variants thereof.

1. Semiconductor device of the Schottky diode type, comprising a substrate constituted of first (2) and second (3) semiconducting layers of a single type of conduction superimposed in said substrate, the second layer (3) being more strongly doped than the first (2), said substrate presenting first (4) and second (5) main surfaces in contact with first (8) and second (6) electrodes, a Schottky barrier being formed between said first electrode (8) and said first layer (2), characterised in that the plurality of islands (9) of a type of conduction which is opposite to that of said first layers (2) are arranged in beds spaced apart in the thickness of said layer (2).

2. Device according to claim 1, characterized in that it comprises, in the first layer (2), a plurality of semiconducting regions (10) of a type of conduction opposite to that of parts of the layer (2) which surrounds them, the plurality of regions (10) extending from the main surface (4) and from the electrode (8) to the inside of the layer (2).

3. Device according to any one of claims 1 and 2, characterized in that the islands (9) have various profiles.

4. Device according to any one of claims 1 to 3, characterized in that the islands (9) are arranged in the form of bands of homogenous or mixed patterns, optionally superimposed on each other in layers or being positioned in a random manner, thus able, according to the shape of the patterns, to present covering areas of the thickness of the superimposed layers.

5. Device according to any one of claims 1 to 4, characterized in that the islands (9) are aligned.

6. Device according to any one of claims 1 to 4, characterized in that the islands (9) are non-aligned.

7. Device according to any one of claims 1 to 4, characterized in that the islands (9) are equidistant.

8. Device according to any one of claims 1 to 4, characterized in that the islands (9) are non-equidistant.

9. Device according to any one of claims 1 to 4, characterized in that the islands (9) are homogenous.

10. Device according to any one of claims 1 to 4, characterized in that the islands (9) are non-homogenous.

11. Device according to any one of claims 1 to 10, characterized in that the islands (9) present a uniform doping.

12. Device according to any one of claims 1 to 10, characterized in that the islands (9) present a non-uniform doping.

13. Device according to any one of claims 1 to 12, characterized in that the islands (9) have a geometric shape with rounded corners.

14. Device according to any one of claims 1 to 13, characterized in that the first layer (2) contains N spaced-apart beds of islands (9), each bed comprising between 1 and 500 islands (9), N varying from 1 to 50.

15. Device according to any one of claims 1 to 14, characterized in that it has a reverse-voltage stability which can be between 100 and 1000 volts, preferably 600 volts.

16. Use of the device according to any one of claims 1 to 15, characterised in that the device is used in the field of current rectification.

17. Use of the device according to any one of claims 1 to 15, characterised in that the device is used as a free-wheel diode integrally or separately fitted with the power-breaker component.

18. Use of the device according to any one of claims 1 to 15, characterised in that the device is used in the field of lighting.

19. Use of the device according to any one of claims 1 to 15, characterised in that the device is used in control of motors, or automobile electronics.
